(19) United States
(12) Patent Application Publication
(10) Pub. No.: US 2007/0192505 A1
(43) Pub. Date: Aug. 16, 2007

(54) Auto-sequencing transmission speed of a data port

(75) Inventor: Kamal Dalmia, Fremont, CA (US)

Correspondence Address: Teranetics Patent Dept, PO Box 641867, San Jose, CA, 95164-1867, US

(73) Assignee: Teranetics, Inc.

(21) Appl. No.: 11/352,669

(22) Filed: Feb. 13, 2006

(51) Int. Cl. G06F 15/16; H03K 5/159

(52) U.S. Cl. 709/233; 375/231

(57) ABSTRACT

Embodiments of methods of auto-sequencing transmission speed of a data port are disclosed. One method includes the data port executing auto-negotiation with a second data port, to determine a highest common transmission speed supported by the data port and the second data port, each port advertising transmission speeds the port can support. Transmission signal qualities of each of four pairs of wires of a cable connected to the data ports are determined. It is then determined whether the transmission signal qualities of the pairs is high enough to support a negotiated transmission speed. If transmission signal qualities of the pairs are below a threshold required for the negotiated transmission speed, then the transmission speed advertised by the port is updated depending upon a degree of failure of the transmission signal qualities of the pairs. The auto-negotiation is then re-executed.

### FIELD OF THE INVENTION

The invention relates generally to network communications. More particularly, the invention relates to a method and apparatus for auto-sequencing transmission speed of a data port.

### BACKGROUND OF THE INVENTION

High-speed networks are continually evolving. The evolution includes a continuing advancement in the operational speed of the networks. The network implementation of choice that has emerged is Ethernet networks physically connected over unshielded twisted pair wiring. Ethernet in its 100BASE-TX form is one of the most prevalent high speed LANs (local area network) for providing connectivity between personal computers, workstations and servers.

High-speed LAN technologies include 100BASE-T (Fast Ethernet) and 1000BASE-T (Gigabit Ethernet). Fast Ethernet technology has provided a smooth evolution from 10 Megabits per second (Mbps) performance of 10BASE-TX to the 100 Mbps performance of 100BASE-TX. Gigabit Ethernet provides 1 Gigabit per second (Gbps) bandwidth with essentially the simplicity of Ethernet. There is a desire to increase operating performance of Ethernet to 10 Gigabit and even greater data rates.

FIG. 1 shows a block diagram of a pair of Ethernet transceivers communicating over a bidirectional transmission channel, according to the prior art. An exemplary transmission channel includes four pairs of copper wire 112, 114, 116, 118. The transceiver pair can be referred to as link partners, and includes a first Ethernet port 100 and a second Ethernet port 105. Both of the Ethernet ports 100, 105 include four transmitter Tₓ, receiver Rₓ, and I/O buffering sections corresponding to each of the pairs of copper wires 112, 114, 116, 118.

An implementation of high speed Ethernet networks includes simultaneous, full bandwidth transmission, in both directions (termed full duplex), within a selected frequency band. When configured to transmit in full duplex mode, Ethernet line cards are generally required to have transmitter and receiver sections of an Ethernet transceiver connected to each other in a parallel configuration to allow both the transmitter and receiver sections to be connected to the same twisted wiring pair for each of four pairs.

As the transmission frequencies increase, attenuation, noise and interference have greater effects on the performance of the data transmission. Exemplary interference includes far end cross-talk (FEXT) and near-end cross-talk (NEXT). NEXT is caused by interference due to signals generated at the near-end of a neighboring twisted pair connection. FEXT is caused by interference due to signals generated at the far-end of a neighboring twisted pair connection. Other interference includes an echo signal, inter-symbol interference (ISI), and alien signal interference. Alien signal interference generally includes interference due to other Ethernet twisted pair LAN connections of cables that may be proximate to the twisted pair cable of the signal of interest.

FIG. 2 is a flow chart that shows a prior art method of auto-negotiating transmission speed of Ethernet ports as shown in FIG. 1. A first step 210 includes the Ethernet ports auto-negotiating a transmission speed. During auto-negotiation, the ports exchange information about the highest common speed supported by the two ports. The auto-negotiation generally only involves two pairs (referred to as the A and B pairs, which are for example, the pairs 112, 114 of FIG. 1) of the four pairs of a twisted pair cable 112, 114, 116, 118. After negotiating the speed, the two ports enter a “startup” sequence which includes a channel training step 220. During training, information, such as, signal to noise ratio of each pair is determined. After training, the ports start a data transmission step 230. After data transmission, the ports begin a step 240 of monitoring the BER (bit error rate) of the data transmission. If the BER is below a threshold, then the data transmission continues. However, if the BER rises above the threshold, rather than analyzing the cause of failure, the prior methods simply attempt the entire negation and training process again. If the process fails N number of times, the port goes back to auto-negotiation with the next lower speed advertised.

If the pairs of cables, more specifically, the A and B pairs 112, 114, suffer from a hard fault, the auto-negotiation fails, and the channel must be replaced. If the pairs of the twisted pair cable suffer from a soft fault, the above process can repeat over and over as the BER continues to be excessive. There has been some suggestion to limit the process to repeating five times, and then indicating a failure. The auto-negotiation can be updated with the next lower advertised transmission speed. However, this failure process of the initially auto-negotiated speed is excessively long.

It is desirable to have an apparatus and method for auto-negotiation between data ports that does not take an excessive amount of time, and provides for optimal transmission speed negotiation.

### SUMMARY OF THE INVENTION

The invention includes an apparatus and method for auto-sequencing transmission speed of a data port. The auto-sequencing provides a time-efficient transmission speed re-sequencing, if a channel connected between the data port and another data port cannot support an initially negotiated speed.

A first embodiment of a method of auto-sequencing transmission speed of a data port includes the data port executing auto-negotiation with a second data port to determine a highest common transmission speed supported by the data port and the second data port. During auto-negotiation, each port advertises transmission speeds the port can support. Transmission signal qualities of each of four pairs of wires of a cable connected to the data ports are determined. It is then determined whether the transmission signal qualities of the pairs is high enough to support a negotiated transmission speed. If transmission signal qualities of the pairs are below a threshold required for the negotiated transmission speed, then the transmission speed advertised by the port is updated depending upon a degree of failure of the transmission signal qualities of the pairs. The auto-negotiation is then re-executed.

Another embodiment of the invention includes another method of auto-sequencing transmission speed of a data port. This embodiment includes the transmission signal quality of each of four pairs of wires of a cable connected to the data ports being determined during a link training phase.

Another embodiment includes another embodiment for auto-sequencing transmission speed of a data port. The embodiment includes transmission signal qualities being determined during a link training phase, and the transmission signal qualities being used to determine coefficients of digital signal processing to be used during data transmission through the data port The transmission signal qualities of the pairs are checked to determine whether enough they are high to support a negotiated transmission speed. If the transmission signal quality of the pairs is below a threshold required for the negotiated transmission speed, then the transmission speed advertised by the port is updated.

Other aspects and advantages of the present invention will become apparent from the following detailed description, taken in conjunction with the accompanying drawings, illustrating by way of example the principles of the invention.

### BRIEF DESCRIPTION OF THE DRAWINGS

The present invention is readily understood by the following detailed description in conjunction with the accompanying drawings, wherein like reference numerals designate like structural elements, and in which:

FIG. 1 shows a block diagram of a transceiver pair communicating over a bi-directional transmission channel, according to the prior art.

FIG. 2 is a flow chart that shows a prior art method of auto-negotiating transmission speed of an Ethernet port.

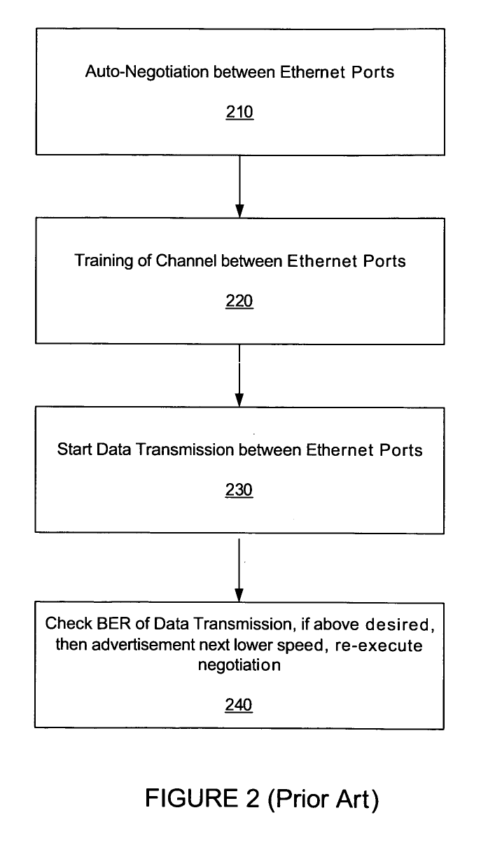

FIG. 3 is a flow chart showing an exemplary method of auto-sequencing transmission speed of a data port that includes modifications in advertised speed depending upon a degree of transmission channel failure.

FIG. 4 is a flow chart showing an exemplary method of auto-sequencing transmission speed of a data port that includes characterizing transmission signal quality during a training phase of the data port.

FIG. 5 is a flow chart showing an exemplary method of auto-sequencing transmission speed of a data port that includes using signal quality parameters that are measured for the purpose of determining transmission signal processing, for determining the modifications in the advertising speed if the initially negotiated speed fails.

FIG. 6 shows a block diagram of an Ethernet port that can utilize the methods of auto-sequencing shown in FIGS. 3, 4, 5.

FIG. 7 shows devices connected to an Ethernet network that can include embodiments of the Ethernet port shown in FIG. 6.

### DETAILED DESCRIPTION

As shown in the drawings for purposes of illustration, the invention is embodied in an apparatus and method for auto-sequencing data ports. An exemplary data port includes an Ethernet data port.

As previously stated, existing Ethernet systems fail a negotiated transmission speed by determining a BER of data transmission. If the BER of the data transmission is determined to be above a desired level, the auto-negotiation is repeated with the same advertised speed. After N number of unsuccessful attempts (typically, for example, five), the negotiated speed is dropped. This process, however, can take a relatively long amount of time. That is, the Ethernet devices go through negotiation, channel training, and data transmission for each attempt. A typical Gigabit system makes five attempts, taking over five seconds. A typical 10 Gigabit system can make five attempts, taking over 12 seconds. After failure, the advertisement of the negotiation lowered to the next lower transmission speed. This process may be repeated for the next lower advertised speed, and then fail again.

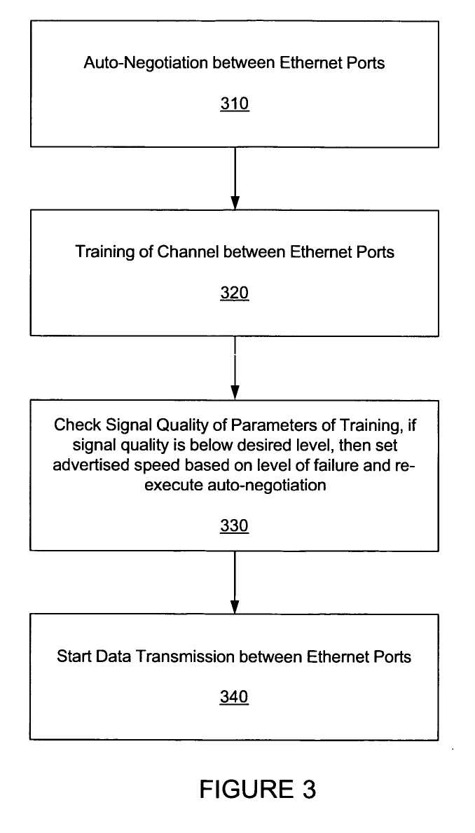

FIG. 3 is a flow chart showing an exemplary method of auto-sequencing transmission speed of a data port that includes modifications in advertised speed of the data port depending upon a degree of transmission channel failure. A first step 310 includes the data port executing auto-negotiation with a second data port, to determine a highest common transmission speed supported by the data port and the second data port, each port advertising transmission speeds the port can support. A second step 320 includes determining a transmission signal quality of each of a plurality of pairs of wires of a cable connected between the data ports. A third step 330 includes determining whether the transmission signal qualities of the pairs are high enough to support a negotiated transmission speed. A fourth step 340 includes determining if the transmission signal quality of the pairs is below a threshold required for the negotiated transmission speed. If below, then the transmission speed advertised by the port is updated depending upon a degree of failure of the transmission signal qualities of the pairs, and the auto-negotiation is re-executed. That is, the failure includes multiple levels, in which each level corresponds with a suggested advertised transmission speed for the next auto-negotiation. The advertised speed can be adjusted to one of multiple speeds depending upon the degree of failure.

Auto-negotiation is a part of the Ethernet standard that allows Ethernet devices to exchange information about their capabilities. One outcome of the information exchange includes a selection of a common communication mode over a link (transmission channel) between the devices having Ethernet data ports. The auto-negotiation provides automatic speed matching between multi-speed ports of the devices. Multi-speed Ethernet data ports that are linked can then take advantage of the highest speed offered by the Ethernet port devices.

After auto-negotiation, the Ethernet devices proceed to a training phase in which the transmission channel (link) between the Ethernet devices is characterized. The training phase includes known (training) signals being transmitted between linked Ethernet port devices. The training signals are transmitted from one Ethernet device, and received at another. Therefore, information can be learned about characteristics of the transmission channel between the Ethernet devices by comparing the received training signals with the known transmitted training signals. The transmission channel information is used for determining the desired signal processing of signals before transmission. That is, the transmission channel information can be used to determine coefficients for signal processing of transmission signals.

The transmission signals can suffer from attenuation, FEXT, NEXT, ISI and alien crosstalk. The digital signal processing mitigates these effects by processing the signals before transmission. There are many different processes and methods of signal processing based upon signal qualities characterized during training, for reducing the effects. Some of these processes are well known.

Exemplary signal quality parameters that are characterized during training include signal to noise ratio (SNR), pair skew and received signal power. The SNR provides information regarding the received signal power relative to the receive noise power. The pair skew provides information regarding the amount of signal skew between wires of a pair versus wires of another pair during transmission (that is, between the transmitter and the receiver). The received signal power provides information regarding attenuation of the transmission signals assuming the transmit power is known.

The signal quality parameters are determined during the training phase. Typically, the training signals occupy much smaller frequency bandwidths than data signals that are transmitted over links (transmission channels) between the Ethernet data ports. For example, exemplary 10GBASE-T Ethernet training includes PAM2 signals, and exemplary 10GBASE-T Ethernet data transmission includes DSQ128 signals. The transmission bandwidth of PAM2 is substantially less than the transmission bandwidth of DSQ128. The-lower bandwidth of PAM2 does not stress the transmitter or the receiver. Therefore, the training at a lower bandwidth (as provided by PAM2 transmission) can provide a more direct approximation of the transmission channel. The prior art which uses BER during data transmission requires the transmitter and the receiver to operate at high bandwidths (such as required by DSQ128), and therefore, is more likely to stress the operating margins of the transmitter and receive, and not provide as good of an approximation of the transmission channel.

The transmission signal qualities determined during training can be additionally used (that is, other than determining coefficients for digital signal processing) for determining the maximum transmission speed through the transmission link between the Ethernet ports. That is, the SNR, pairs skew or received signal power measurements made during training can be used to determine whether the transmission channel between the data ports can support the transmission speed that was negotiated during the auto-negotiation phase between the data ports. If the transmission signal qualities indicate that the transmission channel cannot support the negotiated transmission speed, then the advertised speed of the data port or data ports is decreased for a subsequent auto-negotiation. The advertised speed can be directly adjusted based upon the measured training signal quality. That is, rather than merely decreasing the advertising speed to a next lowest speed, the advertised speed can be directly decreased to a speed that the transmission channel can support.

Unlike the prior art, this method does not wait until a data transmission phase to determine whether the transmission channel between data ports cannot support the negotiated speed. Therefore, this process is more expedient. Additionally, failure can include multiple failure levels which determine which of multiple possible advertised speeds are used in the next auto-negotiation.

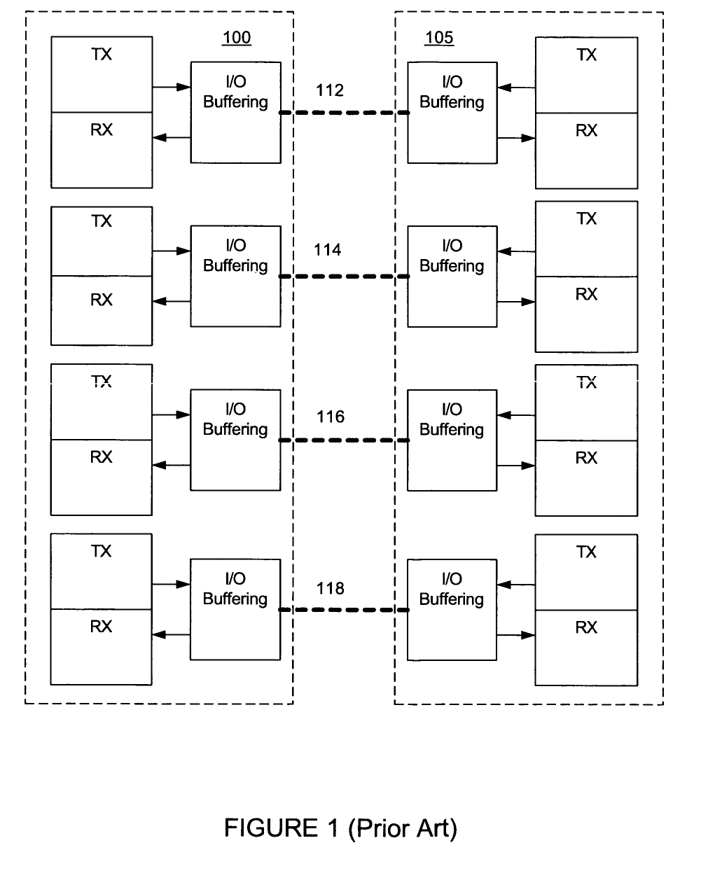

The Ethernet port as shown in FIG. 1 includes four twist pairs which can be referred to as pairs A, B, C and D. 10GBASE-T and 10000BASE-T use all four of the pairs A, B, C and D during data transmission. However, 100BASE-T only uses pairs A and B during data transmission. If an initial negotiation of 10GBASE-T fails the subsequent signal quality parameters tests, a new transmission speed is advertised during the next negotiation. As described here, the new transmission speed advertised is determined by the degree of failure, rather than merely stepping down to the next lower speed as done in the prior art. If, for example, there is a hard fault on either pair C or D, the signal quality parameters determined during training will indicate the existence of this hard fault, and the advertised speed can drop from 10GBASE-T to 100BASE-T. That is, the next lower speed (1000BASE-T) is bypassed. This saves time because decreasing the advertised speed to the next lower speed (for example, going to 1000BASE-T from 10GBASE-T) is a waste of time because 1000BASE-T will fail when pairs C or D have a hard fault. For example, if the amount of signal skew between wires of a pair versus wires of another pair is measured during training to be more than 80 nanoseconds, then the advertised speed is dropped from 10GBASE-T to 100BASE-T because signal skew of this amount suggests that the Ethernet ports can not support 1000BASE-T transmission.

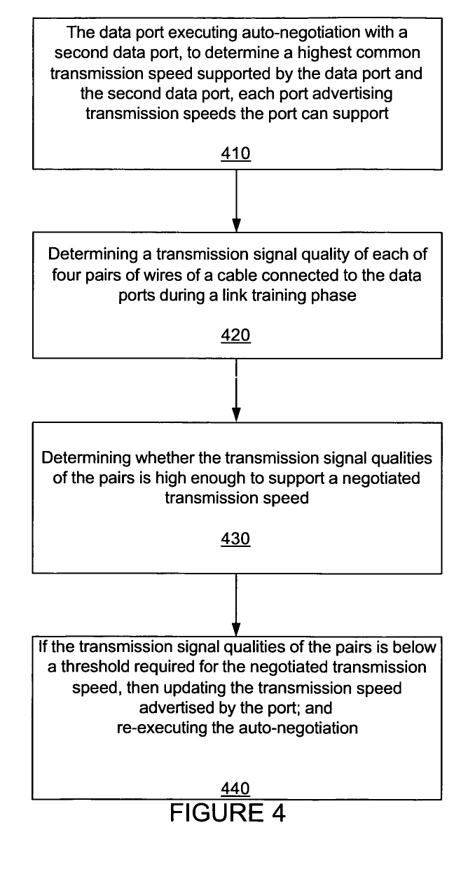

FIG. 4 is a flow chart showing an exemplary method of auto-sequencing transmission speed of a data port that includes characterizing transmission signal quality during a training phase of the data port. A first step 410 includes the data port executing auto-negotiation with a second data port, to determine a highest common transmission speed supported by the data port and the second data port, each port advertising transmission speeds the port can support. A second step 420 includes determining a transmission signal quality of each of four pairs of wires of a cable connected to the data ports during a link training phase. A third step 430 includes determining whether the transmission signal qualities of the pairs are high enough to support a negotiated transmission speed. A fourth step 440 includes if the transmission signal qualities of the pairs is below a threshold required for the negotiated transmission speed, then updating the transmission speed advertised by the port, and re-executing the auto-negotiation.

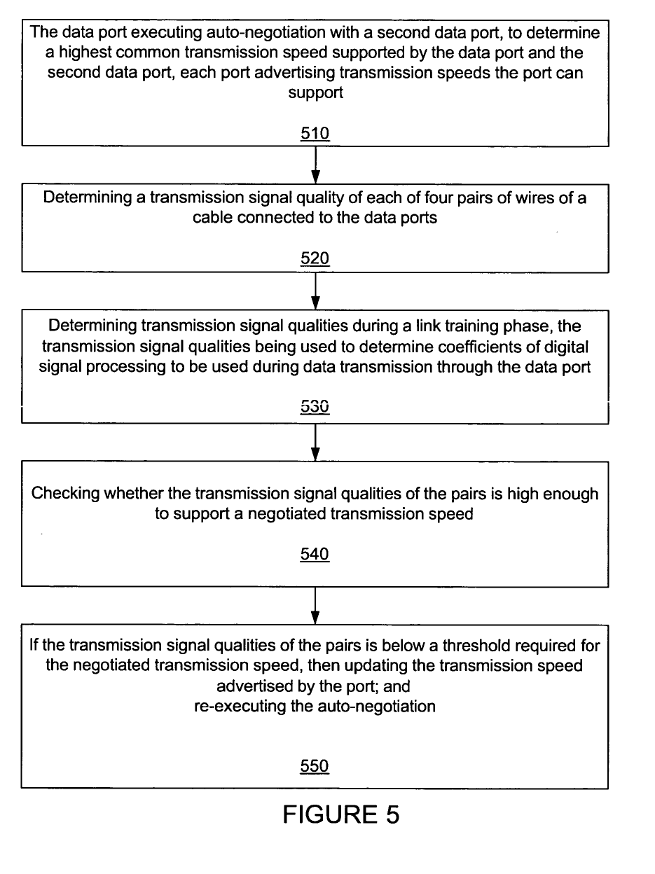

FIG. 5 is a flow chart showing an exemplary method of auto-sequencing transmission speed of a data port that includes using signal quality parameters that are measured for the purpose of determining transmission signal processing, for determining the modifications in the advertising speed if the initially negotiated speed fails. A first step 510 includes the data port executing auto-negotiation with a second data port, to determine a highest common transmission speed supported by the data port and the second data port, each port advertising transmission speeds the port can support. A second step 520 includes determining a transmission signal quality of each of four pairs of wires of a cable connected to the data ports. A third step 530 includes determining transmission signal qualities during a link training phase, the transmission signal qualities being used to determine coefficients of digital signal processing to be used during data transmission through the data port. A fourth step 540 includes checking whether the transmission signal qualities of the pairs is high enough to support a negotiated transmission speed; if the transmission signal qualities of the pairs is below a threshold required for the negotiated transmission speed, then updating the transmission speed advertised by the port, and re-executing the auto-negotiation.

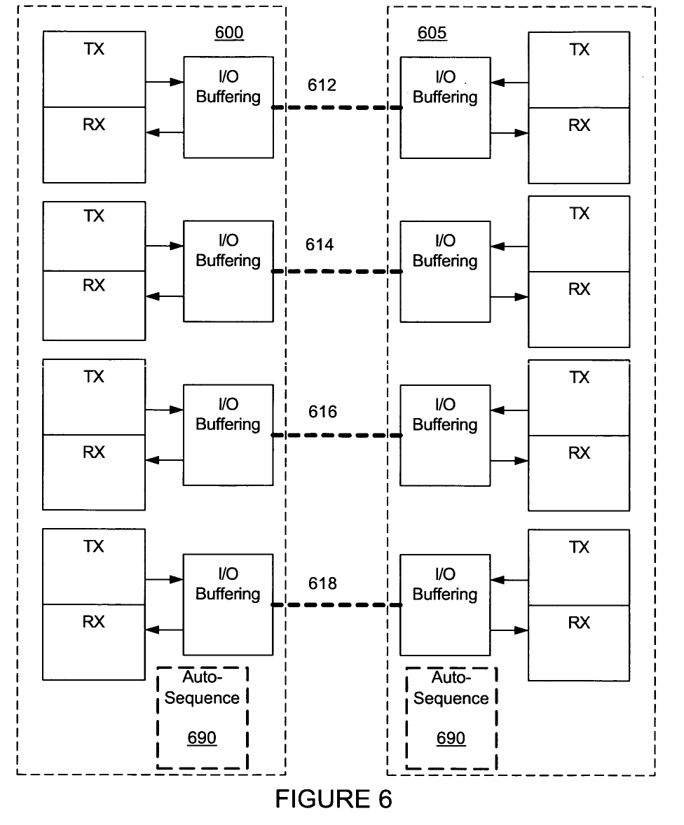

FIG. 6 shows a block diagram of an Ethernet port that can utilize the methods of auto-sequencing shown in FIGS. 3, 4, 5. In an exemplary embodiment, the Ethernet port includes software operable on a processing unit of the Ethernet port. A processing unit that can include the auto-sequencing is shown as the auto-sequencing unit 690. The auto-sequencing units 690 control the auto-sequencing transmission speed of the Ethernet ports 600, 605.

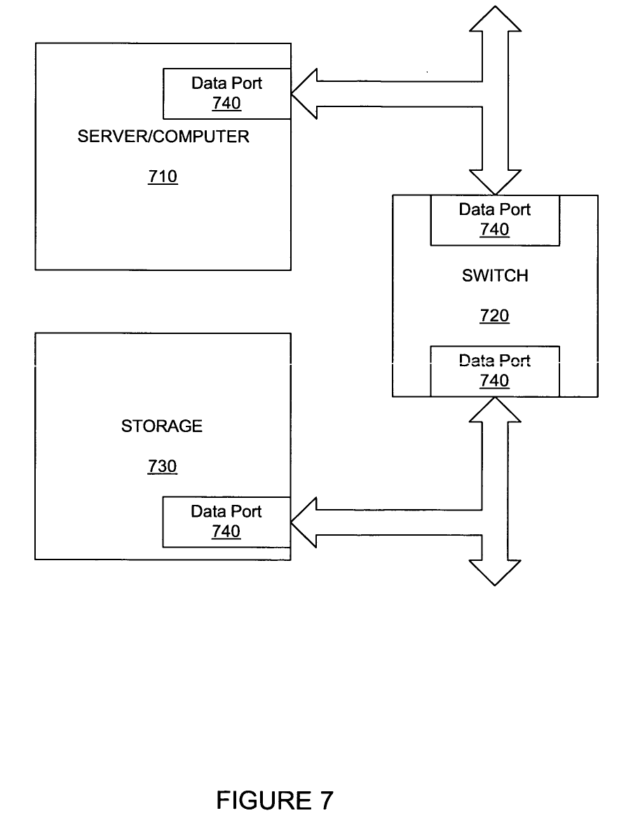

FIG. 7 shows devices connected to an Ethernet network that can include embodiments of an Ethernet port 740 similar to the Ethernet ports shown in FIG. 6. Ethernet transceiver ports 740 as described for transmission of Ethernet signals. The Ethernet ports can be included within a server 710, a switch 720 or a storage device 730. Clearly, other types of devices can use the Ethernet port 740 as well.

Ethernet ports have been used for descriptive purposes. However, it is to be understood that any type of data port executing auto-negotiation can utilize the methods and apparatuses described.

Although specific embodiments of the invention have been described and illustrated, the invention is not to be limited to the specific forms or arrangements of parts so described and illustrated. The invention is limited only by the appended claims.

What is claimed:

1. A method of auto-sequencing transmission speed of a data port, comprising:
the data port executing auto-negotiation with a second data port, to determine a highest common transmission speed supported by the data port and the second data port, each port advertising transmission speeds the port can support;
determining a transmission signal quality of each of a plurality of pairs of wires of a cable connected to the data ports;
determining whether the transmission signal qualities of the pairs is high enough to support a negotiated transmission speed;
if the transmission signal qualities of the pairs is below a threshold required for the negotiated transmission speed, then updating the transmission speed advertised by the port depending upon a degree of failure of the transmission signal qualities of the pairs; and
re-executing the auto-negotiation.

2. The method of claim 1, wherein the greater the degree of failure, the lower the transmission speed advertised.

3. The method of claim 1, wherein the data port comprises an Ethernet port.

4. The method of claim 1, further comprising:
if the transmission signal qualities of the pairs is low enough, indicating a failure of connection between the ports.

5. The method of claim 1, wherein the transmission signal quality is an SNR of training signals transmitted between the data ports.

6. The method of claim 1, wherein the transmission signal quality is a received signal power of training signals transmitted between the data ports.

7. The method of claim 1, wherein the transmission signal quality is a signal pair skew of training signals transmitted between the data ports.

8. The method of claim 1, wherein an initial negotiated transmission speed is 10 Gigabit Ethernet.

9. The method of claim 1, wherein an initial negotiated transmission speed is 1 Gigabit Ethernet.

10. A method of auto-sequencing transmission speed of a data port, comprising:
the data port executing auto-negotiation with a second data port, to determine a highest common transmission speed supported by the data port and the second data port, each port advertising transmission speeds the port can support;
determining a transmission signal quality of each of four pairs of wires of a cable connected to the data ports during a link training phase;
determining whether the transmission signal qualities of the pairs is high enough to support a negotiated transmission speed;
if the transmission signal qualities of the pairs is below a threshold required for the negotiated transmission speed, then updating the transmission speed advertised by the port; and
re-executing the auto-negotiation.

11. The method of claim 10, further comprising setting the transmission speed advertised depending upon a degree of failure of the transmission signal qualities of the pairs.

12. The method of claim 10, wherein the transmission signal quality is an SNR of training signals transmitted between the data ports.

13. The method of claim 10, wherein the transmission signal quality is a received signal power of training signals transmitted between the data ports.

14. The method of claim 10, wherein the transmission signal quality is a signal pair skew of training signals transmitted between the data ports.

15. The method of claim 10, wherein the transmission signal quality is used to determine coefficients of signal processing of transmission signals of the data port to reduce the effects of noise and interference of the transmission signals.

16. The method of claim 10, wherein transmission signal bandwidth during the link training phase is less than transmission signal bandwidth during data transmission.

17. A method of auto-sequencing transmission speed of a data port, comprising:
the data port executing auto-negotiation with a second data port, to determine a highest common transmission speed supported by the data port and the second data port, each port advertising transmission speeds the port can support;
determining a transmission signal quality of each of four pairs of wires of a cable connected to the data ports;
determining transmission signal qualities during a link training phase, the transmission signal qualities being used to determine coefficients of digital signal processing to be used during data transmission through the data port;
checking whether the transmission signal qualities of the pairs is high enough to support a negotiated transmission speed;
if the transmission signal qualities of the pairs is below a threshold required for the negotiated transmission speed, then updating the transmission speed advertised by the port; and
re-executing the auto-negotiation.

18. The method of claim 17, wherein the transmission signal quality is an SNR of training signals transmitted between the data ports.

19. The method of claim 17, wherein the transmission signal quality is a received signal power of training signals transmitted between the data ports.

20. The method of claim 17, wherein the transmission signal quality is a signal pair skew of training signals transmitted between the data ports.

21. The method of claim 17, wherein the transmission signal quality is used to determine coeficients of signal processing of transmission signals of the data port to reduce the effects of noise and interference of the transmission signals.

22. The method of claim 17, wherein transmission signal bandwidth during the link training phase is less than transmission signal bandwidth during data transmission.
